(19) United States
(12) Patent Application Publication
(10) Pub. No.: US 2025/0040036 A1
(43) Pub. Date: Jan. 30, 2025

(54) CIRCUIT BOARD STRUCTURE INCLUDING METAL MATERIALS WITH DIFFERENT THERMAL EXPANSION COEFFICIENTS AND METHOD FOR PRODUCING THE SAME

(71) Applicant: TONG HSING ELECTRONIC INDUSTRIES, LTD., Taipei City (TW)

(72) Inventor: LI-CHUN HUNG, Hsin-Chu County (TW)

(21) Appl. No.: 18/499,188

(22) Filed: Oct. 31, 2023

(30) Foreign Application Priority Data
Jul. 26, 2023 (TW) 112127860

(51) Int. Cl. H05K 1/02; H05K 1/09; H05K 3/40

(52) U.S. Cl. CPC H05K 1/0271; H05K 1/09; H05K 3/4038; H05K 2201/0338; H05K 2201/09509; H05K 2201/09563

(57) ABSTRACT

A circuit board structure including metal materials with different thermal expansion coefficients and a method for producing the same are provided. The circuit board structure includes a core substrate layer, a first wiring layer formed on the core substrate layer, and an insulating dielectric layer formed on the first wiring layer. The insulating dielectric layer has a signal via hole formed at an inner side thereof. The circuit board structure further includes a first metal material and a second metal material formed in the signal via hole. The first metal material is formed on the first wiring layer, and the second metal material is formed on the first metal material. The first metal material has a first thermal expansion coefficient, the second metal material has a second thermal expansion coefficient, and the second thermal expansion coefficient is greater than the first thermal expansion coefficient.

### CROSS-REFERENCE TO RELATED PATENT APPLICATION

This application claims the benefit of priority to Taiwan Patent Application No. 112127860, filed on Jul. 26, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a circuit board structure, and more particularly to a circuit board structure including metal materials with different thermal expansion coefficients and a method for producing the same.

### BACKGROUND OF THE DISCLOSURE

As shown in FIG. 1, in the related art, two adjacent wiring layers L of a conventional circuit board E can be signally connected to each other through a conductive via hole Via and a metal material M (i.e., copper) filled in the conductive via hole Via.

During a process for producing the conductive via hole Via, the metal material M is filled in the conductive via hole Via through a hole-filling electroplating process. Before electroplating, a to-be-plated surface of the circuit board E generally needs to be cleaned to ensure that a plating quality meets practical requirements.

As shown in FIG. 2, if the to-be-plated surface of the circuit board E is not sufficiently cleaned, the finally-formed circuit board E may have an interface fracture C that occurs at an interface between the metal material M filled in the conductive via hole Via and the wiring layers L (or copper layers) during a subsequent high-temperature operation. As a result, electrical signals cannot be transmitted between the two adjacent wiring layers L, and the circuit board E may be determined as malfunctioning due to signal disconnection.

### SUMMARY OF THE DISCLOSURE

In response to the above-referenced technical inadequacies, the present disclosure provides a circuit board structure including metal materials with different thermal expansion coefficients and a method for producing the same.

In order to solve the above-mentioned problems, one of the technical aspects adopted by the present disclosure is to provide a circuit board structure including metal materials with different thermal expansion coefficients. The circuit board structure includes a core substrate layer, a first wiring layer, an insulating dielectric layer, a first metal material, and a second metal material. The first wiring layer is formed on the core substrate layer. The insulating dielectric layer is formed on the first wiring layer. The insulating dielectric layer has a signal via hole formed at an inner side thereof. The first metal material is formed in the signal via hole and on the first wiring layer. The second metal material is formed in the signal via hole and on the first metal material. The first metal material has a first thermal expansion coefficient, the second metal material has a second thermal expansion coefficient, and the second thermal expansion coefficient is greater than the first thermal expansion coefficient.

In order to solve the above-mentioned problems, another one of the technical aspects adopted by the present disclosure is to provide a method for producing a circuit board structure. The method includes: providing a core substrate layer; forming a first wiring layer on a side surface of the core substrate layer; forming an insulating dielectric layer on a side surface of the first wiring layer away from the core substrate layer; forming a signal via hole at an inner side of the insulating dielectric layer, in which the signal via hole is connected to and penetrates through an upper surface and a lower surface of the insulating dielectric layer; forming a first metal material in the signal via hole and on the first wiring layer, in which the first metal material has a first thermal expansion coefficient; and forming a second metal material in the signal via hole and on the first metal material; in which the second metal material has a second thermal expansion coefficient, and the second thermal expansion coefficient is greater than the first thermal expansion coefficient.

Therefore, in the circuit board structure including the metal materials with different thermal expansion coefficients and the method for producing the same provided by the present disclosure, through stacking of the first metal material and the second metal material in the signal via hole and through the design of the thermal expansion coefficients, a signal connection can still be maintained when a fracture occurs at the signal via hole (i.e., when a fracture occurs at an interface between the first metal material and the first wiring layer).

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a conventional circuit board structure in the related art;

FIG. 2 is a schematic view showing occurrence of an interface fracture at an interface between a metal material filled in a conductive via hole and a copper layer in the conventional circuit board structure in the related art;

FIG. 3 is a schematic cross-sectional view of a circuit board structure according to a first embodiment of the present disclosure;

FIG. 4 is a schematic view showing a second metal material in FIG. 3 downwardly generating a compression stress;

FIG. 5 is a schematic view showing another variation of the circuit board structure of FIG. 3;

FIG. 6 is a schematic cross-sectional view of a circuit board structure according to a second embodiment of the present disclosure;

FIG. 7 is a partial enlarged view of part VII of FIG. 6;

FIG. 8 is a schematic view showing a first metal material in FIG. 6 inwardly generating a bending stress; and

FIG. 9 is a flowchart of a method for producing a circuit board structure according to a third embodiment of the present disclosure.

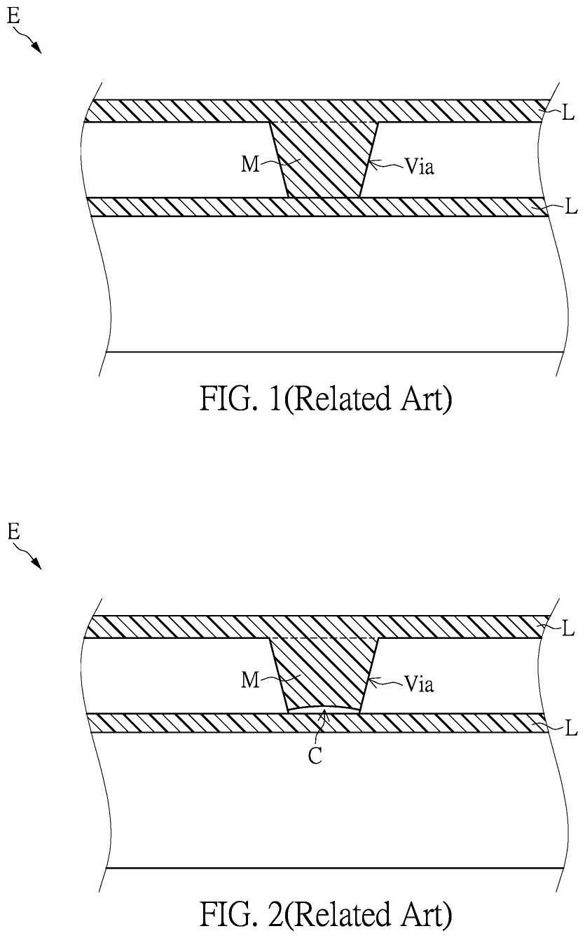

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

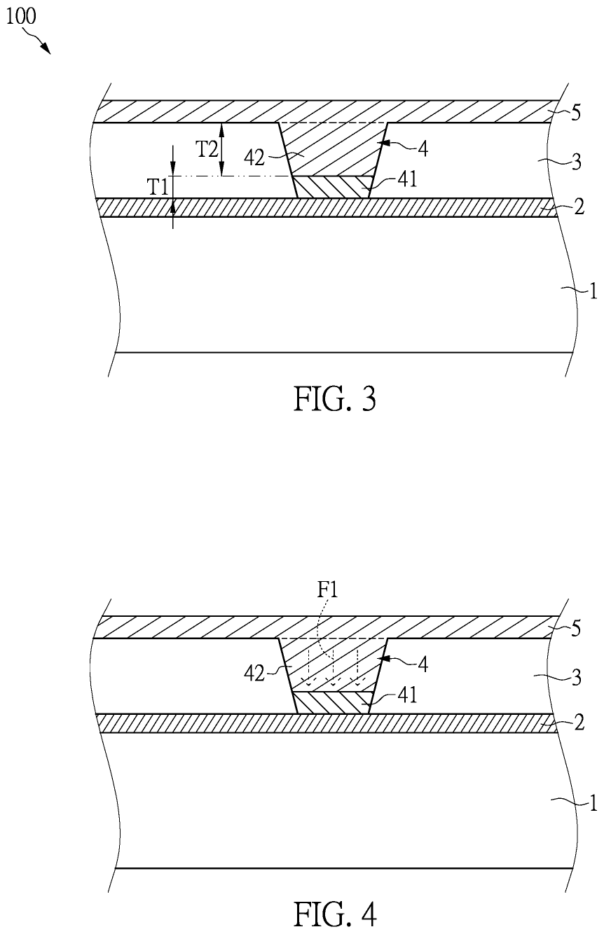

Referring to FIG. 3 and FIG. 4, a first embodiment of the present disclosure provides a circuit board structure 100, which particularly includes metal materials with different thermal expansion coefficients, so as to improve the problem that electrical signals are not able to be transmitted due to a fracture occurring at an interface between a via hole and a copper wiring layer of a circuit board in the related art.

In order to achieve the above purpose, the circuit board structure 100 includes a core substrate layer 1, a first wiring layer 2 and an insulating dielectric layer 3. The first wiring layer 2 is formed on a side surface of the core substrate layer 1, and the insulating dielectric layer 3 is formed on a side surface of the first wiring layer 2 away from the core substrate layer 1.

In the present embodiment, the core substrate layer 1 can be, for example, a fiberglass sheet (e.g., a FR-4 sheet). The first wiring layer 2 can be, for example, a copper wiring layer. The insulating dielectric layer 3 can be, for example, a semi-cured adhesive sheet (e.g., a prepreg or a PP glue). However, the present disclosure is not limited thereto.

Furthermore, the insulating dielectric layer 3 has a signal via hole 4 formed at an inner side thereof. The signal via hole 4 is connected to and penetrates through an upper surface and a lower surface of the insulating dielectric layer 3, and corresponds in position to a part of the first wiring layer 2. In the present embodiment, the signal via hole 4 is a laser drilled hole and has a hole shape that is wide at a top and narrow at a bottom, but is not limited thereto.

In addition, the circuit board structure 100 further includes a first metal material 41 and a second metal material 42, which are sequentially filled in the signal via hole 4 along a direction away from the first wiring layer 2 (or from a bottom portion to a top portion of the signal via hole 4).

In other words, the first metal material 41 is formed in the signal via hole 4 and formed on the first wiring layer 2. The first metal material 41 is directly connected to and in contact with the first wiring layer 2.

In addition, the second metal material 42 is formed in the signal via hole 4 and on a side surface of the first metal material 41 away from the first wiring layer 2. The second metal material 42 is directly connected to and in contact with the first metal material 41.

The first metal material 41 and the second metal material 42 can each be formed by a metal plating process, an electroless plating process, a metal physical deposition process, or a metal chemical deposition process.

In the present embodiment, the first metal material 41 and the second metal material 42 are both in contact with an inner side wall of the signal via hole 4 as shown in FIG. 3, but the present disclosure is not limited thereto.

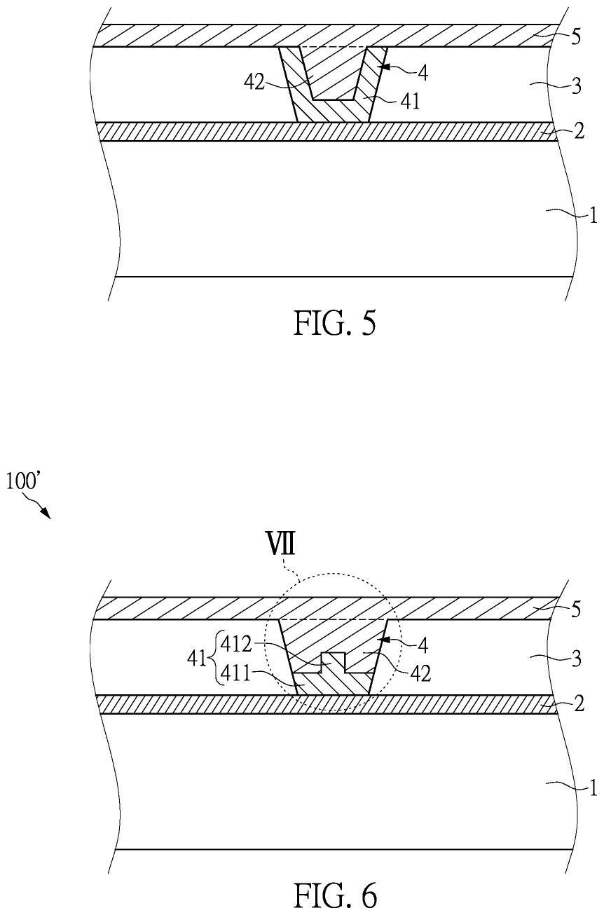

As shown in FIG. 5, in another embodiment of the present disclosure, the first metal material 41 is formed on the first wiring layer 2 and fully covers the inner side wall of the signal via hole 4. The second metal material 42 is filled in a remaining portion of the signal via hole 4, and is not in contact with the inner side wall of the signal via hole 4.

Referring to FIG. 3 and FIG. 4, the first metal material 41 has a first thermal expansion coefficient al, the second metal material 42 has a second thermal expansion coefficient α2, and the second thermal expansion coefficient α2 is greater than the first thermal expansion coefficient al.

As shown in FIG. 4, when the circuit board structure 100 undergoes a high-temperature operation, a volume expansion rate of the second metal material 42 is greater than a volume expansion rate of the first metal material 41, so that the second metal material 42 generates a compression stress F1 towards the first metal material 41.

Accordingly, the first metal material 41 can be tightly in contact with the first wiring layer 2 through the compression stress Ft generated by the second metal material 42, so as to maintain an electrical connection between the first metal material 41 and the first wiring layer 2.

In an embodiment of the present disclosure, the high-temperature operation can be, for example, a high-temperature reflow process, but the present disclosure is not limited thereto.

According to the above configuration, even if an interface between the first metal material 41 and the first wiring layer 2 has a fracture, the first metal material 41 can still be tightly connected to and in contact with the first wiring layer 2 through the compression stress F1 generated by the second metal material 42. Accordingly, the problem of not being able to transmit electrical signals due to a fracture occurring at an interface between a via hole and a copper wiring layer in the related art can be effectively improved.

It is worth mentioning that the thermal expansion coefficient (CTE) referred to in the present embodiment represents a regularity coefficient of a change on geometric properties of a substance as a temperature rises or falls under an action of thermal expansion and contraction.

The thermal expansion coefficients of the first metal material and the second metal material can be coefficients of linear thermal expansion (CLTE), but the present disclosure is not limited thereto.

It is worth mentioning that in some embodiments of the present disclosure, the first metal material 41 and the second metal material 42 filled in the signal via hole 4 can each be at least one of a copper (Cu) metal, a silver (Ag) metal, a gold (Au) metal, a zinc (Zn) metal, and an aluminum (Al) metal, but the present disclosure is not limited thereto.

For example, a coefficient of linear thermal expansion a of the copper (Cu) metal is 16.5×10⁻⁶/K@20° C. (i.e., at 20° C.), and a coefficient of linear thermal expansion a of the silver (Ag) metal is 19.5×10⁻⁶/K@20° C.

In addition, a coefficient of linear thermal expansion a of the gold (Au) metal is 14.2×10⁻⁶/K@20° C., a coefficient of linear thermal expansion a of the zinc (Zn) metal is 36.0×10⁻⁶/K@20° C., and a coefficient of linear thermal expansion a of the aluminum (Al) metal is 23.0×10⁻⁶/K@20° C.

In some embodiments of the present disclosure, the second metal material 42 can be, for example, the copper metal that has a second thermal expansion coefficient α2 of 16.5×10⁻⁶/K@20° C., and the first metal material 41 can be, for example, the gold metal that has a first thermal expansion coefficient al of 14.2×10⁻⁶/K@20° C.

Alternatively, the second metal material 42 can be, for example, the silver metal that has a second thermal expansion coefficient α2 of 19.5×10⁻⁶/K@20° C., and the first metal material 41 can be, for example, the copper metal that has a first thermal expansion coefficient al of 16.5×10⁻⁶/K@20° C.

It is worth mentioning that in the above embodiments, the second thermal expansion coefficient α2 of the second metal material 42 is greater than the first thermal expansion coefficient al of the first metal material 41.

From another perspective, the first thermal expansion coefficient al of the first metal material 41 and the second thermal expansion coefficient α2 of the second metal material 42 each ranges from 10×10⁻⁶/K@20° C. to 40×10⁻⁶/K@20° C.

In addition, a difference between the second thermal expansion coefficient α2 of the second metal material 42 and the first thermal expansion coefficient al of the first metal material 41 is not less than 1×10⁻⁶/K@20° C., and is preferably not less than 2×10⁻⁶/K@20° C.

However, it should be noted that the above-mentioned embodiments are provided for illustrative purposes only, and the present disclosure is not limited thereto.

Referring to FIG. 3 and FIG. 4, in the signal via hole 4, the first metal material 41 has a first thickness T1, the second metal material 42 has a second thickness T2, and the second thickness T2 of the second metal material 42 is greater than the first thickness T1 of the first metal material 41.

In some embodiments of the present disclosure, a sum of the first thickness T1 and the second thickness T2 is defined as a total thickness. The first thickness T1 of the first metal material 41 relative to the total thickness accounts for 15% to 45% (preferably 20% to 40%), and the second thickness T2 of the second metal material 42 relative to the total thickness accounts for 55% to 85% (preferably 60% to 80%).

Based on the above-mentioned thickness ratios, the compression stress F1 generated by the second metal material 42 on the first metal material 41 during the high-temperature operation is sufficient for the first metal material 41 to be tightly in contact with the first wiring layer 2, so as to maintain the electrical connection.

Furthermore, in the present embodiment, the circuit board structure 100 further includes a second wiring layer 5, and the second wiring layer 5 is formed on a side surface of the insulating dielectric layer 3 away from the first wiring layer 2. From another perspective, the first wiring layer 2 and the second wiring layer 5 are respectively formed on two opposite side surfaces of the insulating dielectric layer 3. The first wiring layer 2 is connected to the first metal material 41, and the second wiring layer 5 is connected to the second metal material 42.

In one embodiment of the present disclosure, the first wiring layer 2 and the first metal material 41 can be, for example, formed separately in different electroplating processes or metal deposition processes. In addition, the second wiring layer 5 and the second metal material 42 can be, for example, formed in the same electroplating process or metal deposition process. However, the present disclosure is not limited thereto.

### Second Embodiment

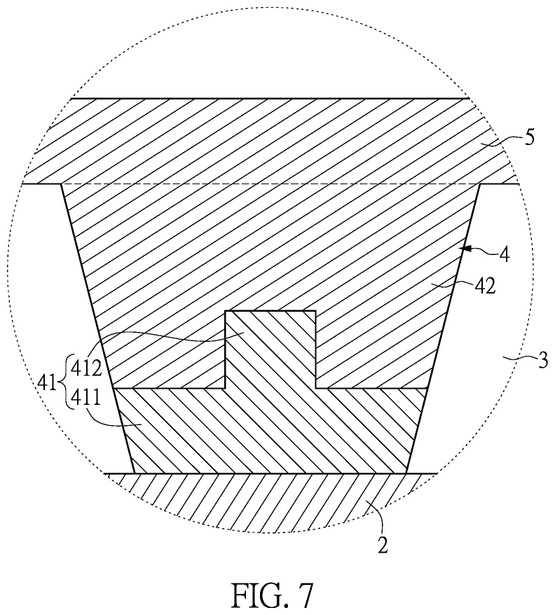

Referring to FIG. 6 to FIG. 8, a second embodiment of the present disclosure provides a circuit board structure 100′, and the circuit board structure 100′ includes a core substrate layer 1, a first wiring layer 2, an insulating dielectric layer 3, and a second wiring layer 5. The first wiring layer 2 is formed on a side surface of the core substrate layer 1. The insulating dielectric layer 3 is formed on a side surface of the first wiring layer 2 away from the core substrate layer 1. The second wiring layer 5 is formed on a side surface of the insulating dielectric layer 3 away from the first wiring layer 2.

The insulating dielectric layer 3 has a signal via hole 4 formed at an inner side thereof. The signal via hole 4 is connected to and penetrates through an upper surface and a lower surface of the insulating dielectric layer 3. The circuit board structure 100′ further includes a first metal material 41 and a second metal material 42, which are sequentially filled in the signal via hole 4. The first metal material 41 is formed on the first wiring layer 2, and the second metal material 42 is formed on the first metal material 41. The first metal material 41 has a first thermal expansion coefficient al, the second metal material 42 has a second thermal expansion coefficient α2, and the second thermal expansion coefficient α2 is greater than the first thermal expansion coefficient al. The first metal material 41 is connected to the first wiring layer 2, and the second metal material 42 is connected to the second wiring layer 5, so that the first wiring layer 2 is electrically connected to the second wiring layer 5.

In the present disclosure, the circuit board structure 100′ of the second embodiment is substantially the same as the circuit board structure 100 of the first embodiment. A main difference between these two embodiments is that the first metal material 41 of the second embodiment further has a base portion 411 and a protruding portion 412 formed on the base portion 411, and a width of the base portion 411 is greater than a width of the protruding portion 412, so that the second metal material 42 forms a convex structure.

Furthermore, the base portion 411 is formed on the first wiring layer 2, and the base portion 411 is directly connected to and in contact with the first wiring layer 2. The protruding portion 412 is embedded in the second metal material 42, so that the first metal material 41 is engaged with the second metal material 42. Accordingly, a contact area between the first metal material 41 and the second metal material 42 can be increased to effectively increase a bonding strength between heterogeneous materials (i.e., a bonding strength between the first metal material 41 and the second metal material 42).

Similar to the first embodiment, when the circuit board structure 100′ undergoes a high-temperature operation, a volume expansion rate of the second metal material 42 is greater than a volume expansion rate of the first metal material 41, so that the second metal material 42 generates a compression stress F1 toward the first metal material 41. Accordingly, the first metal material 41 is continuously and firmly in contact with the first wiring layer 2 through the compression stress F1 generated by the second metal material 42, so as to maintain an electrical connection between the first metal material 41 and the first wiring layer 2.

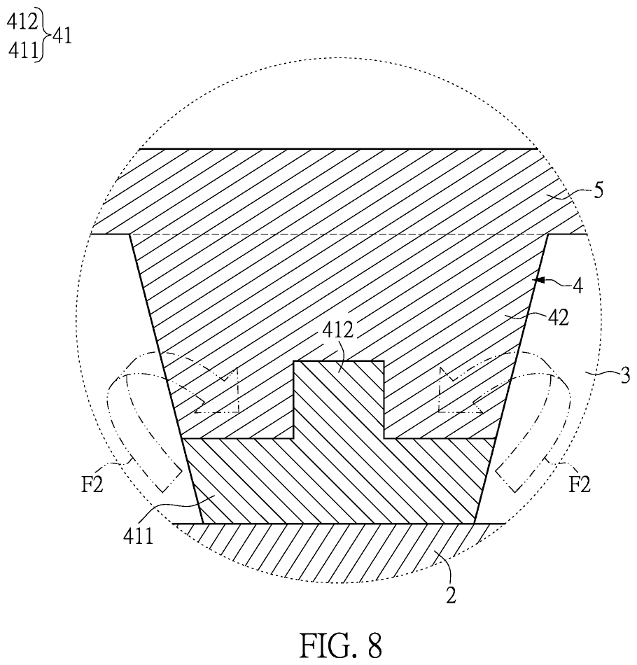

Furthermore, when a temperature of the circuit board structure 100′ is cooled down from the high-temperature operation, a volume shrinkage rate of the first metal material 41 is greater than a volume shrinkage rate of the second metal material 42, so that the base portion 411 generates a bending stress F2 toward the protruding portion 412 (as shown in FIG. 8). In this way, the first metal material 41 can be more tightly combined with the second metal material 42, and the first metal material 41 downwardly contacts the first wiring layer 2 to maintain the electrical connection.

According to the above configuration, although a fracture occurs at an interface between the first metal material 41 and the first wiring layer 2, the first metal material 41 can still be continuously and firmly connected to and in contact with the first wiring layer 2.

Accordingly, the problem of not being able to transmit electrical signals due to a fracture occurring at an interface between a via hole and a copper wiring layer in the related art can be effectively improved.

### Third Embodiment

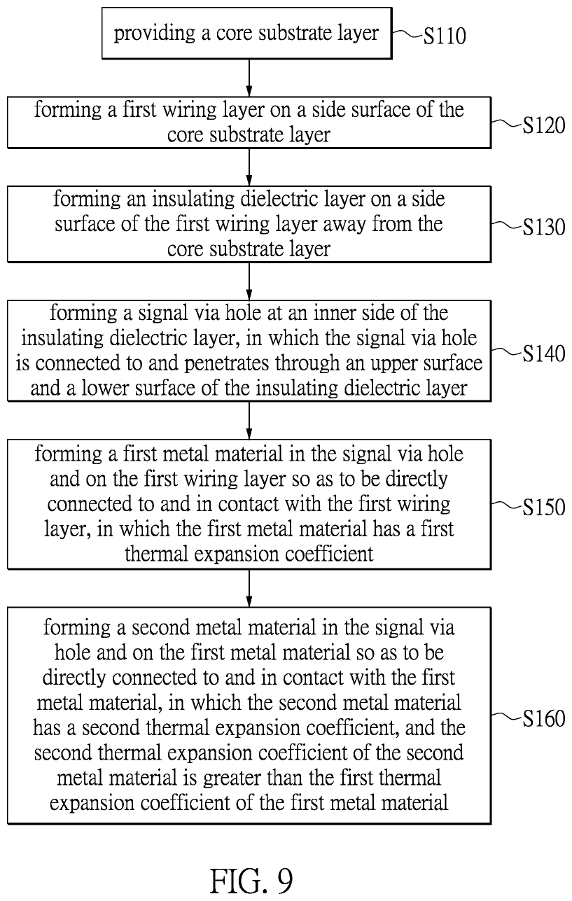

The above descriptions relate to the structural features and the material features of the circuit board structures 100 and 100′ according to the first embodiment and the second embodiment of the present disclosure. As shown in FIG. 9, a third embodiment of the present disclosure further provides a method for producing a circuit board structure, which includes step S110 to step S160.

It should be noted that the sequence and actual implementations of each step described in the present embodiment can be adjusted according to practical requirements, and are not limited to those described in the present embodiment.

Step S110 includes: providing a core substrate layer 1.

Step S120 includes: forming a first wiring layer 2 on a side surface of the core substrate layer 1.

Step S130 includes: forming an insulating dielectric layer 3 on a side surface of the first wiring layer 2 away from the core substrate layer 1.

Step S140 includes: forming a signal via hole 4 at an inner side of the insulating dielectric layer 3, in which the signal via hole 4 is connected to and penetrates through an upper surface and a lower surface of the insulating dielectric layer 3. In addition, the signal via hole 4 corresponds in position to a part of the first wiring layer 2.

Step S150 includes: forming a first metal material 41 in the signal via hole 4 and on the first wiring layer 2, so as to be directly connected to and in contact with the first wiring layer 2. The first metal material 41 can have a flat shape as shown in FIG. 3, or have a convex shape as shown in FIG. 6. In addition, the first metal material 41 has a first thermal expansion coefficient al.

Step S160 includes: forming a second metal material 42 in the signal via hole 4 and on the first metal material 41, so as to be directly connected to and in contact with the first metal material 41. In addition, the second metal material 42 has a second thermal expansion coefficient α2, and the second thermal expansion coefficient α2 of the second metal material 42 is greater than the first thermal expansion coefficient al of the first metal material 41.

In some embodiments of the present disclosure, the first metal material 41 and the second metal material 42 can each be formed in the signal via hole 4 by at least one of a metal electroplating process, an electroless plating process, a metal physical deposition process, and a metal chemical deposition process.

### Beneficial Effects of the Embodiments

In conclusion, through the design of the stacking of the first metal material and the second metal material in the signal via hole and through the design of the thermal expansion coefficients, the circuit board structure including the metal materials with different thermal expansion coefficients and the method for producing the same provided by the present disclosure can maintain the signal connection when a breakage occurs at the signal via hole (i.e., at an interface between the first metal material and the first wiring layer.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A circuit board structure including metal materials with different thermal expansion coefficients, comprising:
a core substrate layer;
a first wiring layer formed on the core substrate layer;
an insulating dielectric layer formed on the first wiring layer, wherein the insulating dielectric layer has a signal via hole formed at an inner side thereof;
a first metal material formed in the signal via hole and on the first wiring layer; and
a second metal material formed in the signal via hole and on the first metal material;
wherein the first metal material has a first thermal expansion coefficient, the second metal material has a second thermal expansion coefficient, and the second thermal expansion coefficient is greater than the first thermal expansion coefficient.

2. The circuit board structure according to claim 1, wherein a volume expansion rate of the second metal material is greater than a volume expansion rate of the first metal material, so that the second metal material generates a compression stress on the first metal material when the circuit board structure undergoes a high-temperature operation; wherein the first metal material is compressed by the second metal material to be in continuous contact with the first wiring layer, so as to maintain electrical connection between the first metal material and the first wiring layer.

3. The circuit board structure according to claim 1, wherein, in the signal via hole, the first metal material has a first thickness, the second metal material has a second thickness, and the second thickness of the second metal material is greater than the first thickness of the first metal material.

4. The circuit board structure according to claim 3, wherein a sum of the first thickness and the second thickness is defined as a total thickness, the first thickness of the first metal material relative to the total thickness accounts for 15% to 45%, and the second thickness of the second metal material relative to the total thickness accounts for 55% to 85%.

5. The circuit board structure according to claim 1, wherein the first thermal expansion coefficient of the first metal material and the second thermal expansion coefficient of the second metal material each range from 10×10⁻⁶/K@20° C. to 40×10⁻⁶/K@20° C., and a difference between the second thermal expansion coefficient and the first thermal expansion coefficient is not less than 1×10⁻⁶/K@20° C.

6. The circuit board structure according to claim 1, further comprising: a second wiring layer formed on a side surface of the insulating dielectric layer away from the first wiring layer; wherein the first wiring layer is connected to the first metal material, and the second wiring layer is connected to the second metal material.

7. The circuit board structure according to claim 1, wherein the first metal material has a base portion and a protruding portion formed on the base portion, and a width of the base portion is greater than a width of the protruding portion, so that the first metal material forms a convex structure.

8. The circuit board structure according to claim 7, wherein the base portion is formed on the first wiring layer, and the protruding portion is embedded in the second metal material, so that the first metal material is engaged with the second metal material.

9. The circuit board structure according to claim 8, wherein a volume shrinkage rate of the first metal material is greater than a volume shrinkage rate of the second metal material, so that the base portion generates a bending stress on the protruding portion when the circuit board structure is cooled down.

10. A method for producing a circuit board structure, comprising:
providing a core substrate layer;
forming a first wiring layer on a side surface of the core substrate layer;
forming an insulating dielectric layer on a side surface of the first wiring layer away from the core substrate layer;
forming a signal via hole at an inner side of the insulating dielectric layer, wherein the signal via hole is connected to and penetrates through an upper surface and a lower surface of the insulating dielectric layer;
forming a first metal material in the signal via hole and on the first wiring layer, wherein the first metal material has a first thermal expansion coefficient; and
forming a second metal material in the signal via hole and on the first metal material, wherein the second metal material has a second thermal expansion coefficient, and the second thermal expansion coefficient is greater than the first thermal expansion coefficient.
